(19) United States
(12) Patent Application Publication
(10) Pub. No.: US 2019/0206732 A1
(43) Pub. Date: Jul. 4, 2019

(54) THREE-DIMENSIONAL SEMICONDUCTOR DEVICE AND METHOD FOR MANUFACTURING THE SAME

(71) Applicant: MACRONIX INTERNATIONAL CO., LTD., Hsinchu (TW)

(72) Inventors: Wei-Min CHEN, Yuanlin City (TW); Cheng-Wei LIN, Taipei City (TW); Shou-Wei HUANG, Hsinchu City (TW)

(21) Appl. No.: 15/857,964

(22) Filed: Dec. 29, 2017

(51) Int. Cl. H01L 21/768; H01L 27/11568; H01L 27/11582; H01L 23/522; H01L 23/528; H01L 23/532; H01L 23/535; H01L 21/02; H01L 21/3205

(52) U.S. Cl. CPC H01L 21/76895; H01L 21/32053; H01L 27/11582; H01L 23/5226; H01L 23/5283; H01L 23/53271; H01L 23/53257; H01L 23/535; H01L 21/76805; H01L 21/76816; H01L 21/76883; H01L 21/02068; H01L 21/32055; H01L 21/32051; H01L 27/11568

(57) ABSTRACT

A three-dimensional semiconductor device is provided, includes a substrate having an array area and a staircase area; a stack structure having multi-layers formed on the substrate, and the multi-layers comprising conductive layers alternating with insulating layers on the substrate, the stack structure comprising cell-stacks formed on the substrate and disposed in the array area; a conductive channel formed on the substrate and disposed by extending vertically to the multi-layers in the array area; a conductive plug formed on the conductive channel; and a plug contact formed on the conductive plug. The conductive plug includes a polysilicon portion formed on and electrically connected to the conductive channel, and a metal-containing portion formed on the polysilicon portion, wherein the plug contact is electrically connected to the metal-containing portion.

### BACKGROUND

### Field of the Invention

The disclosure relates in general to a three-dimensional (3D) semiconductor device and a method for manufacturing the same are provided, and more particularly to a conductive plug on the channel of a 3D semiconductor device comprising a metal-containing portion which a plug contact is landed on.

### Description of the Related Art

A nonvolatile semiconductor memory device is typically designed to securely hold data even when power is lost or removed from the memory device. Various types of nonvolatile memory devices have been proposed in the related art. Also, manufactures have been looking for new developments or techniques combination for stacking multiple planes of memory cells, so as to achieve greater storage capacity. For example, several types of multi-layer stackable NAND-type flash memory structures have been proposed. However, the typical three-dimensional (3D) semiconductor device still suffers from some problems.

For example, for a 3D NAND structure, ohmic contact for the surfaces of the polysilicon plugs and the vias (ex: the contact vias connecting the conductive plug and the multilayered connectors, also known as VA0) is one of key factors, which dominates on-current performance of the cells. For improving the on-current performance of the cells in 3D semiconductor device, surface treatment can be adopted for ohmic contact of metal (such as tungsten, W) and polysilicon. However, it is required to cover the surfaces of either metal or polysilicon since different treatments are required for treating the surfaces of metal and polysilicon, which is time-consuming and make the process complicated. Please refer to FIG. 1, which shows relationships of cells percentages vs. on-current of conventional 3D semiconductor devices. If a surface treatment for metal (ex: W) is conducted and no poly surface treatment is performed, the tail issue occurs, as indicated by curves (1)-(3). If a poly surface treatment is conducted and no surface treatment for metal is performed, as indicated by curve (4), it obviously improves on-current tail performance, but suffered from the high resistance problems of metals. Therefore, it is a challenge to improve the electrical performances of a 3D semiconductor device such as no tail issue as well as low resistance, and the device is manufactured by a simple process.

### SUMMARY

The disclosure relates to a three-dimensional (3D) semiconductor device and a method for manufacturing the same. According to the embodiment, a conductive plug formed on the conductive channel (ex: vertical channel) comprises a polysilicon portion formed on and electrically connected to the conductive channel, and a metal-containing portion formed on the polysilicon portion, wherein a plug contact is landed on the metal-containing portion. According to the embodiment, polysilicon and metal-containing material(s) can be subjected to different surface treatments, thereby significantly improving the electrical performance of a 3D semiconductor device in the application.

According to one embodiment of the present disclosure, a three-dimensional (3D) semiconductor device is provided, comprising: a substrate, having an array area and a staircase area; a stack structure having multi-layers formed on the substrate, and the multi-layers comprising conductive layers alternating with insulating layers on the substrate, the stack structure comprising cell-stacks formed on the substrate and disposed in the array area; a conductive channel, formed on the substrate and disposed in the array area, the conductive channel extending vertically to the multi-layers and downwardly to the substrate; a conductive plug formed on the conductive channel; and a plug contact formed on the conductive plug. The conductive plug comprises a polysilicon portion formed on and electrically connected to the conductive channel, and a metal-containing portion formed on the polysilicon portion, wherein the plug contact is electrically connected to the metal-containing portion.

According to one embodiment of the present disclosure, a method of manufacturing a 3D semiconductor device is provided, comprising: providing a substrate having an array area and a staircase area; forming a stack structure having multi-layers on the substrate; forming a conductive channel on the substrate and disposed in the array area, the conductive channel extending vertically to the multi-layers and downwardly to the substrate; forming a conductive plug on the conductive channel, and the conductive plug comprising a polysilicon portion electrically connected to the conductive channel, and a metal-containing portion formed on the polysilicon portion; and forming a plug contact on the conductive channel, wherein the plug contact is electrically connected to the metal-containing portion.

The disclosure will become apparent from the following detailed description of the preferred but non-limiting embodiments. The following description is made with reference to the accompanying drawings.

### BRIEF DESCRIPTION OF THE DRAWINGS

FIG. 1 shows relationships of cells percentages vs. on-current of conventional 3D semiconductor devices.

FIG. 2A-FIG. 2D illustrate a method of manufacturing a 3D semiconductor structure having a conductive plug according to an embodiment of the present disclosure.

FIG. 3A-FIG. 3D illustrate one of applicable methods for manufacturing a 3D semiconductor structure with contact vias after forming a conductive plug according to an embodiment of the present disclosure.

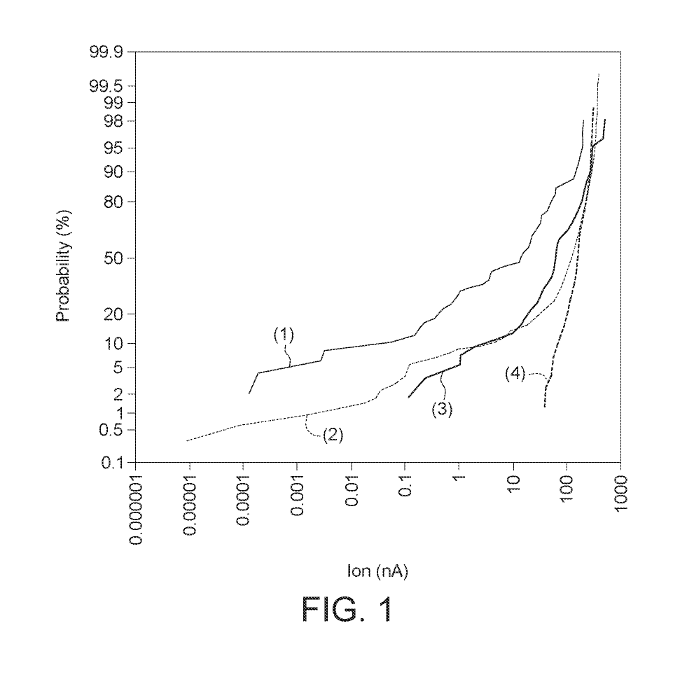

### DETAILED DESCRIPTION

In the embodiments of the present disclosure, a three-dimensional (3D) semiconductor device and a method for manufacturing the same are provided. According to a 3D semiconductor device of the embodiment, a conductive plug formed on the conductive channel (ex: vertical channel) comprises a polysilicon portion formed on and electrically connected to the conductive channel, and a metal-containing portion (ex: metal or metal silicide) formed on the polysilicon portion, wherein a plug contact is landed on the metal-containing portion. According to the embodiment, the metal-containing portion of the conductive plug, the conductive slit and the multilayered connectors all contains (the same or different) metal(s), Thus, after forming the vias in the dielectric layer for exposing the metal-containing portion of the conductive plug, the conductive slit and the multilayered connectors, a metal surface treatment (such as W surface treatment) can be adopted for treating those metal-containing surfaces. Also, according to the embodied method, a poly surface treatment can be performed on the polysilicon portion of the conductive plug before forming the metal-containing portion. That is, in the embodied method, the surface treatments for treating the surfaces of polysilicon and metal-containing material(s) can be performed separately and completely, thereby significantly improving the electrical performance of a 3D semiconductor device in the application. For example, the conventional tail issue occurred due to the solely tungsten (W) surface treatment (i.e. lacking poly surface treatment) and high resistance problems of the conductive slit and cell gates (ex: WLs in a 3D vertical-channel (VC) semiconductor device) can be solved. Moreover, the method of the embodiment causes no damage to the related layers and components of the structure, and the method of the embodiment is also suitable for manufacturing the 3D semiconductor structure with large number of the stacking layers without adopting time-consuming and expensive manufacturing procedures. Thus, the embodied structure and method of manufacturing the same are suitable for mass production.

The embodiment of the present disclosure could be implemented in many different 3D semiconductor structures in the applications, such as any flash memory, NAND, NOR and non-volatile memory with vertical structure. For example, the embodiment could be applied to, but not limited to, the 3D vertical-channel (VC) semiconductor devices. The embodiment is provided hereinafter with reference to the accompanying drawings for elaborating the method of manufacturing the 3D semiconductor structure of the disclosure and the structure manufactured by the same. However, the present disclosure is not limited thereto. The descriptions disclosed in the embodiments of the disclosure such as detailed structures, manufacturing procedures and material selections are for illustration only, not for limiting the scope of protection of the disclosure.

Also, it is noted that not all embodiments of the invention are shown. Modifications and variations can be made without departing from the spirit of the disclosure to meet the requirements of the practical applications. Thus, there may be other embodiments of the present disclosure which are not specifically illustrated. It is also important to point out that the illustrations may not be necessarily be drawn to scale. Thus, the specification and the drawings are to be regard as an illustrative sense rather than a restrictive sense.

Moreover, use of ordinal terms such as “first”, “second”, “third” etc., in the specification and claims to describe an element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

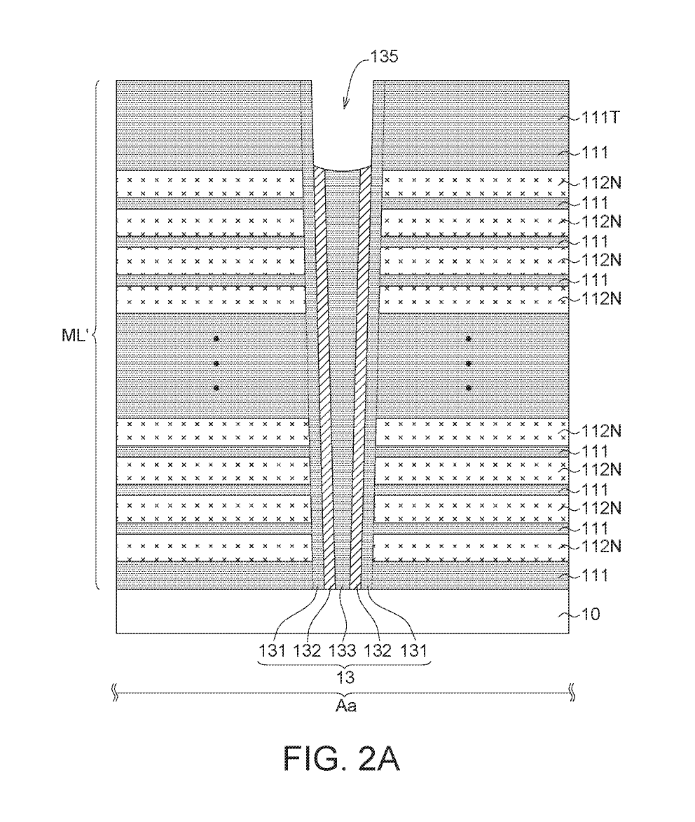

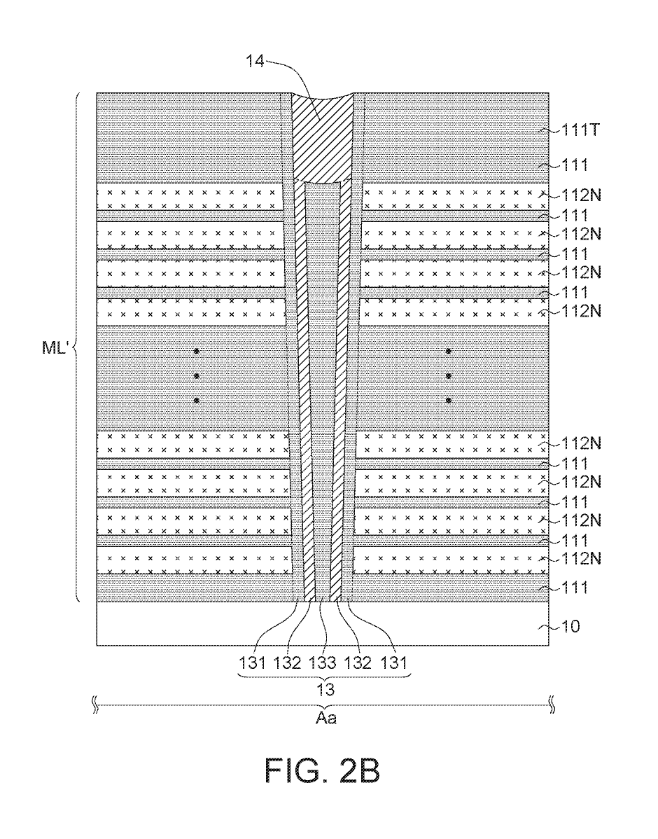

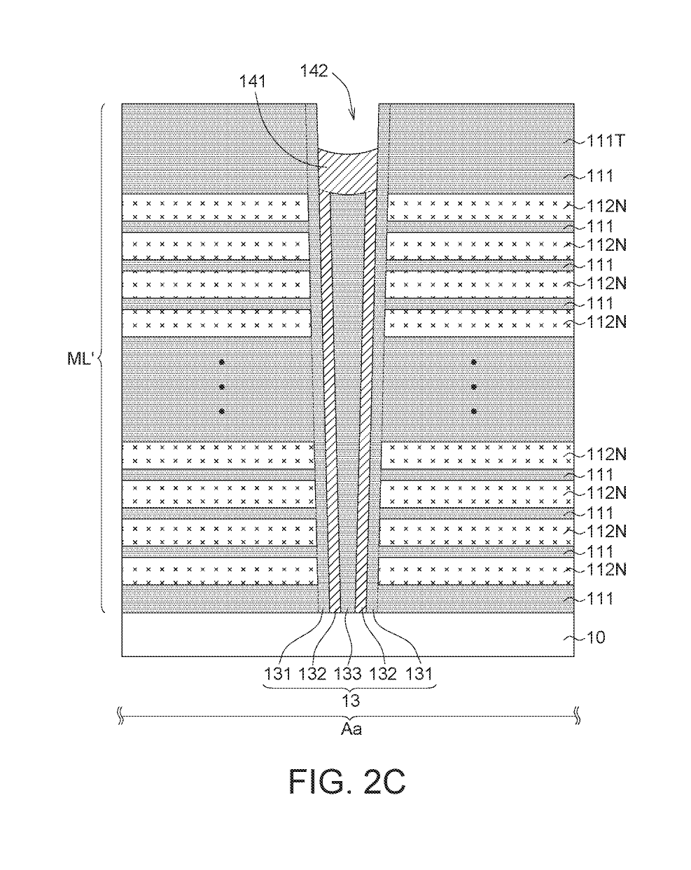

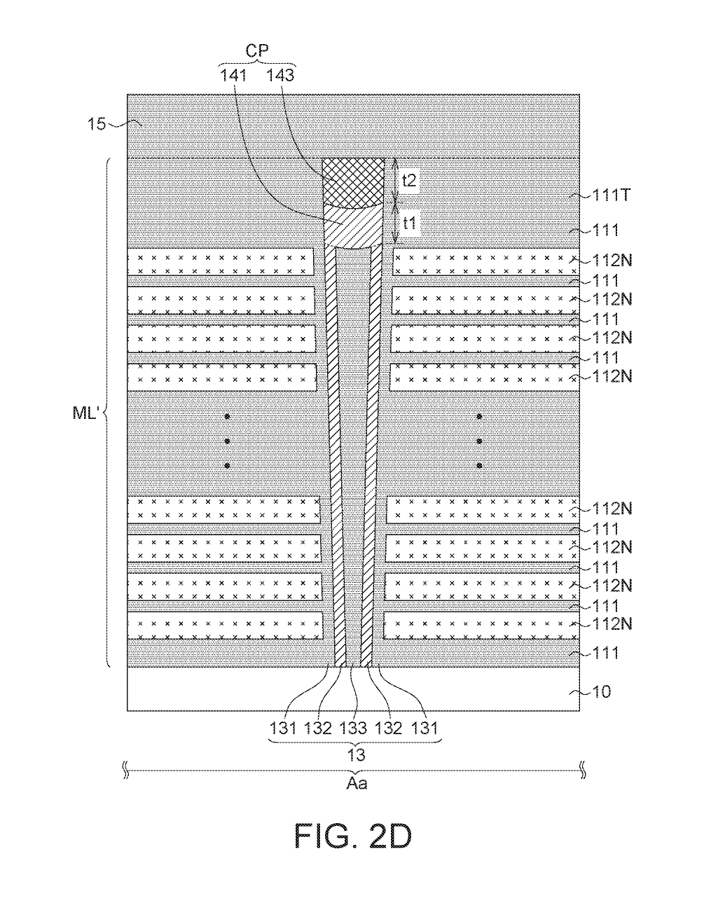

FIG. 2A-FIG. 2D illustrate a method of manufacturing a 3D semiconductor structure having a conductive plug according to an embodiment of the present disclosure. First, a substrate 10 is provided, and a stack structure having multi-layers ML′ is formed on the substrate, wherein the multi-layers ML′ so far comprise several insulating layers 111 (such as the oxide layers) alternating with the dummy layers 112N (such as the silicon nitrite (SiN) layers). Then, a channel structure 13, extended vertically to the multi-layers ML′ and downwardly to the substrate 10, is formed in the array area Aa.

Before forming the channel structure 13, a through hole extending downwardly to the substrate and penetrating the multi-layers ML′ is formed. In one example for forming a channel structure 13, an ONO layer (i.e. a charge trapping layer) is deposited over the multi-layers ML′ and at the sidewalls of the through hole; a polysilicon layer (i.e. as a material layer of a conductive channel) is deposited on the ONO layer along the sidewalls of the ONO layer in the through hole; followed by insulation deposition (ex: oxide deposition). Then, an etching process is performed to remove the polysilicon layer and the ONO layer above the multi-layers (ex: above a top insulating layer 111T of the multi-layers ML′).

In one embodiment, as shown in FIG. 2A, a channel structure 13 comprises a charge trapping layer 131 (functioning as a memory layer) at the sidewalls of the through hole, a conductive channel 132 (such as a polysilicon channel layer for controlling the conductive layers of the multi-layers)(ex: undoped polysilicon) deposited along the charge trapping layer 131 (ex: the polysilicon channel layer is deposited at the sidewalls of the ONO layer in the through hole), and a dielectric medium layer 133 filling up the rest space inside the through hole. The dielectric medium layer 133 can be oxide layer or air. For example, a flowable oxide (ex: commercially available in solution as FOx® Flowable Oxide, which is one of the most intensively studied low k spin-on dielectrics (SOD)) is deposited for filling the remaining space in the through hole as the dielectric medium layer 133. Also, in one embodiment, the charge trapping layer 131 functioning as a memory layer could be an ONO layer or an ONONO layer or an ONONONO layer. Also, as shown in FIG. 2A, a trench 135 is formed above the conductive channel 132.

Noted that in the exemplified drawings of the embodiment, a macaroni-type channel configuration (i.e. the polysilicon is partially filled as a channel layer in the hole) is provided for illustration. However, the disclosure is not limited thereto. The polysilicon can be fully fills the channel hole as a channel layer for meeting the requirements of the practical application. The disclosure is not limited to one particular kind.

Next, after forming the trench 135 above the conductive channel 132, a polysilicon plug 14 is formed in the trench 135, as shown in FIG. 2B. In one example for forming the polysilicon plug 14, another polysilicon layer can be deposited on the multi-layers and fills up the trench 135, followed by etching the polysilicon layer back, thereby forming the polysilicon plug 14 in the trench 135.

Afterwards, a recess 142 is formed by removing a portion of the polysilicon plug 14, so as to form a polysilicon portion 141 remained on the conductive channel 132 and the dielectric medium layer 133, as shown in FIG. 2C.

According to one embodiment, the method further comprises performing a first surface treatment on the polysilicon portion 141 for improving ohmic contact. For example, the first surface treatment could be a wet clean procedure, such as using diluted HF for cleaning oxide residues remained on the polysilicon portion 141. Other treatments able to conduct oxide loss would be applicable.

Next, a metal-containing portion 143 is formed on the polysilicon portion 141, and the metal-containing portion 143 fills up the recess 142, as shown in FIG. 2D. Thus, a conductive plug CP comprising the polysilicon portion and the metal-containing portion is formed. In one example, a metal-containing layer is formed on the multi-layers and fills up the recess 142. The metal-containing layer is subjected to a chemical-mechanical polishing (CMP) procedure for removing the portions not deposited in the recess. Then, a dielectric layer 15 (ex: an oxide layer) is deposited on the conductive plug CP and above the multi-layers ML′. The dielectric layer 15 as deposited is not only for covering the conductive plug CP and the multi-layers ML′, but also for providing sufficient dielectric thickness for subsequently manufacturing procedures.

In one example, the metal-containing portion 143 comprises metal silicide or pure metal (such as WSi or W), or other applicable materials. Also, in one embodiment, the metal-containing portion 143 has a thickness t2 in a range of about 200 Å-400 Å. In another embodiment, the metal-containing portion 143 has a thickness t2 in a range of about 200 Å-300 Å, and the polysilicon portion 141 has a thickness t1 in a range of 300 Å-400 Å. However, the thickness t2 of the metal-containing portion 143 could be larger than, or equal to or less than the thickness t1 of the polysilicon portion 141, the disclosure has no particular limitation thereto. It is noted that those numerical values described herein are provided for illustration, not for limitation. Additionally, in one example, a barrier such as Ti/TiN is deposited first, followed by forming the metal-containing portion 143 as known.

For clearly illustration, although only one conductive channel 132 and one conductive plug CP in an array area Aa of the substrate 10 are depicted in FIG. 2A-FIG. 2D; it is, of course, known that there would be several conductive channel 132 and conductive plugs CP formed in the practical application. Additionally, the subsequently manufacturing procedures after forming embodied conductive plugs for manufacturing a 3D semiconductor structure are exemplified herein.

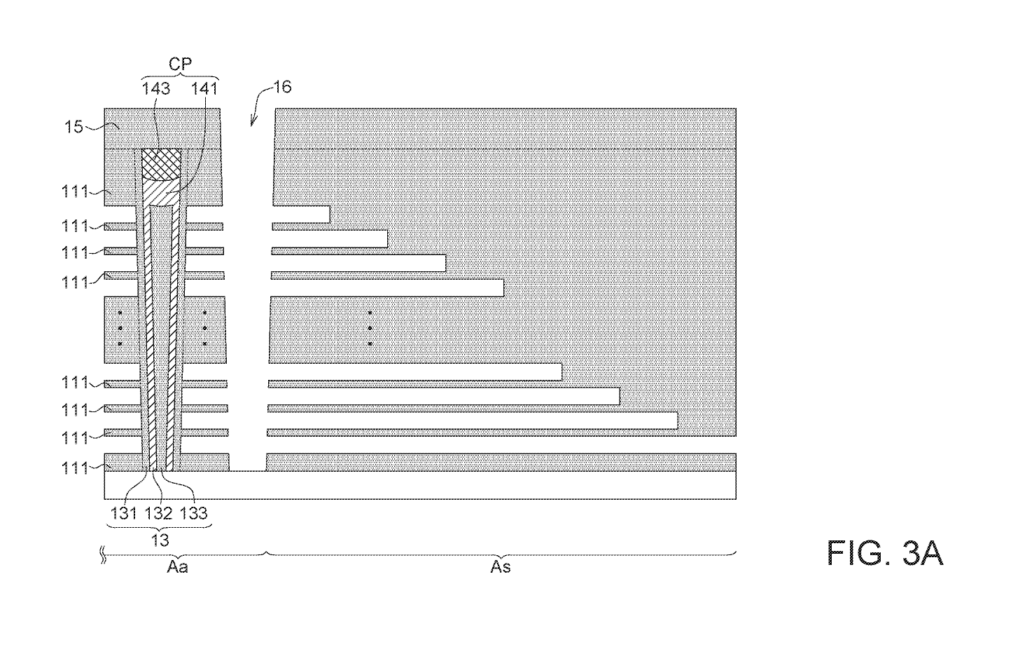

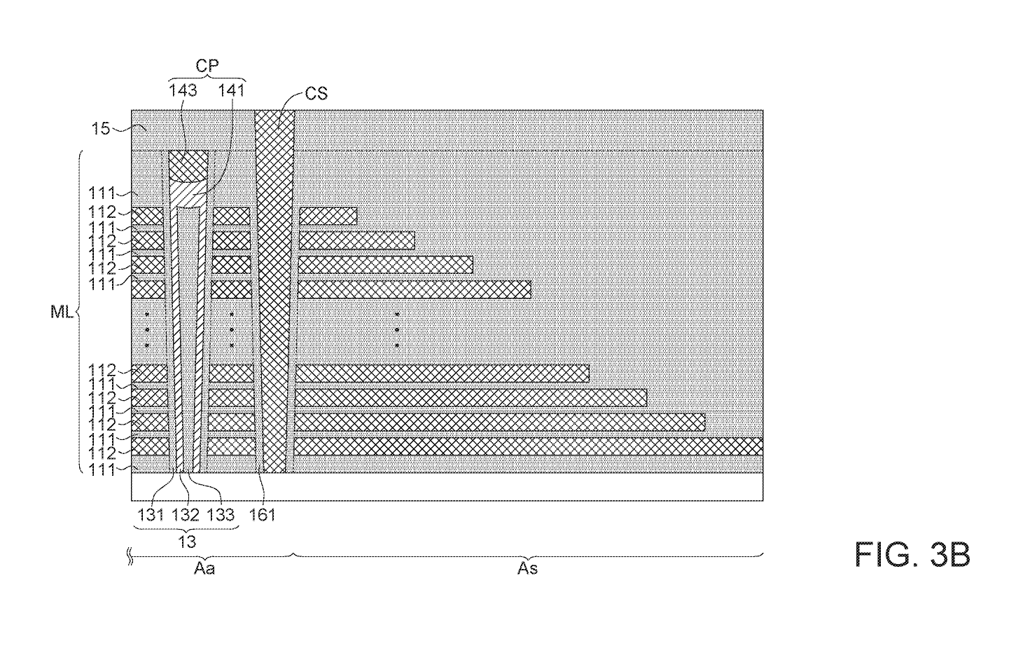

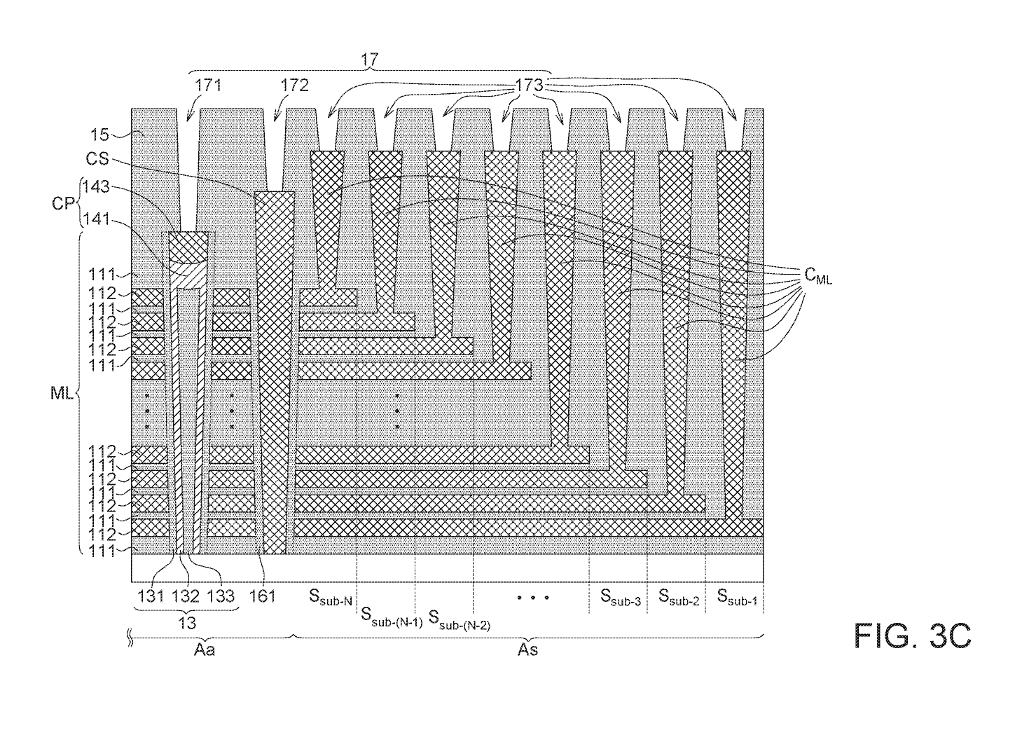

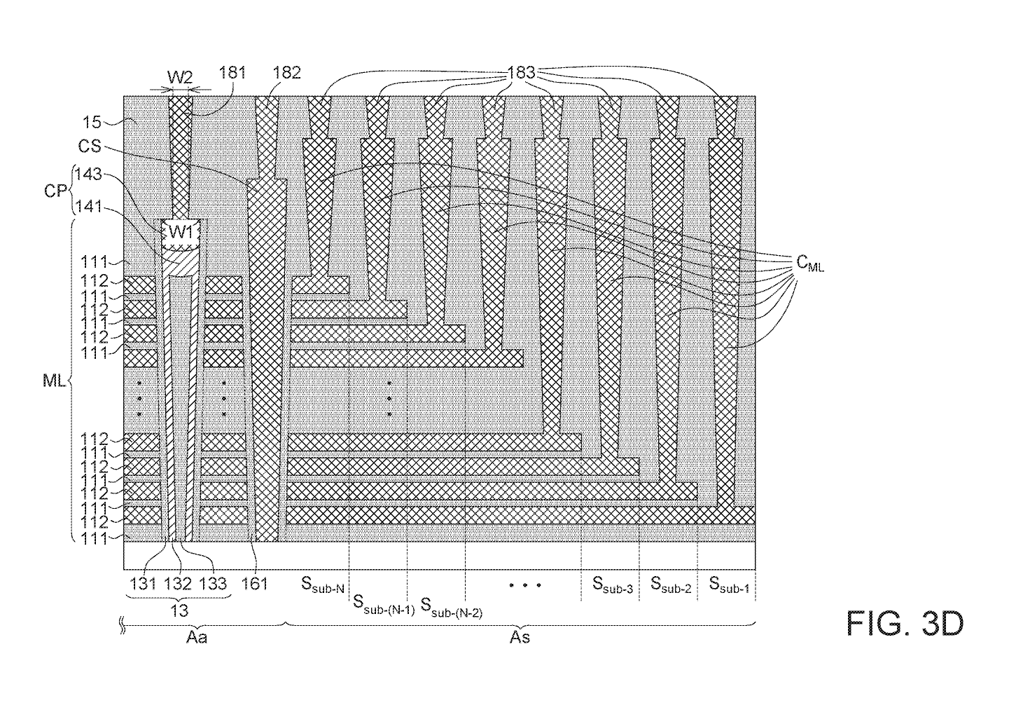

Please refer to FIG. 3A-FIG. 3D, which illustrate one of applicable methods for manufacturing a 3D semiconductor structure with contact vias after forming a conductive plug according to an embodiment of the present disclosure. Typically, a stack structure comprises: cell-stacks formed on the substrate 10 and disposed in an array area Aa; and sub-stacks formed on the substrate 10 and disposed in relation to the N steps of a staircase area As to form respective contact regions. In this exemplification, an array area Aa and a staircase area As of the substrate 10 are depicted for illustration.

As shown in FIG. 3A, a slit 16 is formed in the array area Aa, and the slit 16 is extended vertically to the multi-layers and downwardly to the substrate 10. Also, the dummy layers 112N (such as the SiN layers) of the multi-layers ML′ are emptied through the slit 16.

Then, the dummy layers 112N (such as the SiN layers) of the multi-layers ML′ are replaced by the conductive layers 112, followed by separating the conductive layers 112 in different cell planes, as shown in FIG. 3B. Also, a conductive material is formed in the slit 16 to form a conductive slit CS, wherein the multi-layers ML of the stack structure in FIG. 3B comprise the conductive layers 112 alternating with insulating layers 111 on the substrate 10. In one example, a downward extending direction of the conductive slit CS is substantially in parallel to a downward extending direction of the conductive channel 132.

In one example, after removing the dummy layers (ex: SiN) and depositing a conductive material layer (i.e. the conductive layers 112, such as tungsten (W)) instead, the conductive material layer is etched back for the disconnection between the conductive materials in different cell planes, so as to form the conductive layers 112 of the multi-layers ML in different cell planes. In one embodiment, the conductive layers 112 in different cell planes function as gate electrodes in a VC-type 3D semiconductor device. Then, before forming the conductive slit CS, a dielectric layer 161, such as an oxide layer, can be deposited in the slit 16 as a liner, and the dielectric layer 161 seals the ends of the conductive layers 112 in different cell planes.

Additionally, in one example, a barrier such as Ti/TiN is deposited at the sidewalls of the slit 16, and a conductive material such as tungsten (W) is then deposited for filling the slit 16. The typical procedure such as tungsten CMP is conducted to form the conductive slit CP.

In one example, the staircase area As comprising N steps is depicted, N is an integer one or greater, wherein the sub-stacks (i.e. S_{sub}-1-S_{sub}-N) of the stack structure is disposed in relation to the N steps of the staircase area As to form respective contact regions. After formation of the conductive slit CP, several multilayered connectors C_{ML} are formed for connecting to landing areas on the conductive layers 112 in each of the sub-stacks. Then, several vias 17, such as the vias 171-173, are formed in the dielectric layer 15 for at least exposing the metal-containing portion 143 of the conductive plug CP, the conductive slit CS and the multilayered connectors C_{ML}, respectively. As shown in FIG. 3C, the metal-containing portion 143 of the conductive plug CP is exposed by the via 171, the conductive slit CS is exposed by the via 172, and the multilayered connectors C_{ML} are exposed by the vias 173.

According to one embodiment, the method further comprises performing a second surface treatment on the metal-containing portion 143, the conductive slit CS and the multilayered connectors C_{ML}, for improving ohmic contact. For example, the second surface treatment could be a dry clean procedure (such as a dry etch by plasma treatment to remove the impurities on the surfaces). The second surface treatment for metal can significantly solve conventional problems for high resistance of the conductive slit and cell gates (ex: WLs in a 3D vertical-channel (VC) semiconductor device).

Afterwards, as shown in FIG. 3D, a contact material is deposited in the vias 171-173, so as to form a plug contact 181 in the via 171 for electrically connecting the metal-containing portion 143; a slit contact 182 in the via 172 for electrically connecting the conductive slit CS; and contact vias 183 in the vias 173 for electrically connecting the multilayered connectors C_{ML}, respectively.

As shown in FIG. 3D, according to the structure of the embodiment, the metal-containing portion 143 has a first width W1, the plug contact 181 has a second width W2, and the first width W1 is larger than the second width W2. The first width W1 and the second width W2 are parallel to each other, and measured at the planes parallel to the substrate 10. In one embodiment, the first width W1 is 2 times to 4 times larger than the second width W2. In another embodiment, the first width W1 is 2.5 times to 3.5 times larger than the second width W2. In one embodiment, the first width W1 is about 3 times larger than the second width W2. It is noted that those numerical values described herein are provided for illustration, not for limitation.

Additionally, the metal-containing portion 143 of the embodiment may comprise metal silicide such as WSi, or pure metal such as W, or other suitable materials. The metal-containing portion 143, the conductive slit CS and the multilayered connectors C_{ML} may comprise the same metal or different metals. In one embodiment, the metal-containing portion 143 of the conductive plug CP and the conductive layers 112 of the multi-layers ML (after gate replacement; FIG. 3B) comprise the same metal. In one embodiment, the conductive slit CS and the metal-containing portion 143 of the conductive plug CP comprise the same metal. In one embodiment, the conductive slit CS, the metal-containing portion 143, the conductive layers 112 of the multi-layers ML and the multilayered connectors C_{ML} may comprise the same metal, or the same material. Also, the plug contact 181, the slit contact 182 and the contact vias 183 may comprise the same metal or the same material as that of the metal-containing portion 143.

According to the aforementioned descriptions, a three-dimensional (3D) semiconductor device is provided by forming a conductive plug on the conductive channel (ex: vertical channel), wherein the conductive plug comprises a polysilicon portion formed on and electrically connected to the conductive channel, and a metal-containing portion (ex: metal or metal silicide) formed on the polysilicon portion. A plug contact is landed on the metal-containing portion according to the embodiment. The method of the embodiment uses a self-aligned polysilicon etching back approach to overcome the challenge of polysilicon and metal (such as W) surface treatments. The self-aligned polysilicon etching back approach of the embodiment can perform a polysilicon surface treatment first (ex: the first surface treatment on the polysilicon portion 141), and a metal surface treatment is adopted for treating those metal-containing surfaces (ex: the second surface treatment on the metal-containing portion 143, the conductive slit CS and the multilayered connectors C_{ML} which all contain the same or different metals). Thus, in the embodied method, the surface treatments for treating the surfaces of polysilicon and metal(s) can be performed separately and completely, thereby significantly improving the electrical performance of a 3D semiconductor device in the application, such as obtaining better on-current performance (ex: no tail issue) and maintaining sufficiently low resistances for the conductive slit, cell gates and contacts. Moreover, the method of the embodiment causes no damage to the related layers and components of the structure, and the method of the embodiment is also suitable for manufacturing the 3D semiconductor structure with large number of the stacking layers without adopting time-consuming and expensive manufacturing procedures. Thus, the embodied structure and method of manufacturing the same are suitable for mass production.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in the array area of a 3D semiconductor device, the shapes or positional relationship of the elements, such as multi-layers and channels of the cell configurations, contact slits and multilayered connectors, would be modified or changed depending on the types of the semiconductor devices of the application, and the manufacturing details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A three-dimensional (3D) semiconductor device, comprising:
a substrate, having an array area and a staircase area;
a stack structure having multi-layers formed on the substrate, and the multi-layers comprising conductive layers alternating with insulating layers on the substrate, the stack structure comprising cell-stacks formed on the substrate and disposed in the array area;
a conductive channel, formed on the substrate and disposed in the array area, the conductive channel extending vertically to the multi-layers and downwardly to the substrate;
a conductive plug, formed on the conductive channel, and the conductive plug comprising:
a polysilicon portion, formed on and electrically connected to the conductive channel; and
a metal-containing portion, formed on the polysilicon portion; and
a plug contact, formed on the conductive plug and electrically connected to the metal-containing portion.

2. The 3D semiconductor device according to claim 1, wherein the metal-containing portion has a first width, the plug contact has a second width, and the first width is larger than the second width.

3. The 3D semiconductor device according to claim 2, wherein the first width is 2 times to 4 times larger than the second width.

4. The 3D semiconductor device according to claim 1, wherein the metal-containing portion comprises metal silicide or metal.

5. The 3D semiconductor device according to claim 1, wherein the metal-containing portion has a thickness in a range of 200 Å to 400 Å.

6. The 3D semiconductor device according to claim 1, wherein the metal-containing portion and the conductive layers of the multi-layers comprise the same metal.

7. The 3D semiconductor device according to claim 1, further comprising a conductive slit extending vertically to the multi-layers and downwardly to the substrate, wherein the conductive slit and the metal-containing portion of the conductive plug comprise the same metal.

8. The 3D semiconductor device according to claim 1, wherein the staircase area comprising N steps, N is an integer one or greater, and the stack structure further comprises sub-stacks formed on the substrate and disposed in relation to the N steps of the staircase area to form respective contact regions, and the 3D semiconductor device further comprises:
multilayered connectors connected to landing areas on the conductive layers in each of the sub-stacks; and
contact vias, formed on and electrically connected to the multilayered connectors, respectively.

9. The 3D semiconductor device according to claim 8, wherein the metal-containing portion of the conductive plug and the multilayered connectors comprise the same metal.

10. The 3D semiconductor device according to claim 8, wherein the metal-containing portion, the plug contact, the multilayered connectors and the contact vias are made of the same material.

11. A method of manufacturing a three-dimensional (3D) semiconductor device, comprising:
providing a substrate having an array area and a staircase area;
forming a stack structure having multi-layers on the substrate;
forming a conductive channel on the substrate and disposed in the array area, the conductive channel extending vertically to the multi-layers and downwardly to the substrate;
forming a conductive plug on the conductive channel, and the conductive plug comprising:
a polysilicon portion, electrically connected to the conductive channel; and
a metal-containing portion formed on the polysilicon portion; and
forming a plug contact on the conductive channel, wherein the plug contact is electrically connected to the metal-containing portion.

12. The method according to claim 11, wherein forming the conductive plug comprises:
forming a trench above the conductive channel;
forming a polysilicon plug in the trench;
forming a recess by removing a portion of the polysilicon plug, and the polysilicon portion as remained formed on the conductive channel; and
forming the metal-containing portion on the polysilicon portion and the metal-containing portion filling up the recess, wherein the conductive plug comprises the polysilicon portion and the metal-containing portion.

13. The method according to claim 12, further comprising:
performing a first surface treatment on the polysilicon portion before forming the metal-containing portion.

14. The method according to claim 13, further comprising:
depositing a dielectric layer on the conductive plug and above the multi-layers;
forming a slit extending vertically to the multi-layers, and the slit extending downwardly to the substrate;
replacing dummy layers of the multi-layers by conductive layers, and separating the conductive layers in different cell planes; and
forming a conductive material in the slit to form a conductive slit,
wherein after replacing the dummy layers and forming the conductive slit, the multi-layers of the stack structure comprise the conductive layers alternating with insulating layers on the substrate, and the stack structure comprises cell-stacks formed on the substrate and disposed in the array area.

15. The method according to claim 14, wherein the staircase area comprising N steps, N is an integer one or greater, and the stack structure further comprises sub-stacks formed on the substrate and disposed in relation to the N steps of the staircase area to form respective contact regions, and the method further comprises:
forming multilayered connectors connected to landing areas on the conductive layers in each of the sub-stacks;
forming vias in the dielectric layer for exposing the metal-containing portion of the conductive plug, the conductive slit and the multilayered connectors, respectively;
depositing a contact material in the vias, so as to form the plug contact electrically connected to the metal-containing portion, a slit contact electrically connected to the conductive slit, and contact vias formed on and electrically connected to the multilayered connectors, respectively.

16. The method according to claim 15, further comprising:
performing a second surface treatment on the metal-containing portion, the conductive slit and the multilayered connectors, before depositing the contact material in the vias,
wherein the metal-containing portion, the conductive slit and the multilayered connectors comprise same metal or different metals.

17. The method according to claim 11, wherein the metal-containing portion has a first width, the plug contact has a second width, and the first width is larger than the second width.

18. The method according to claim 17, wherein the first width is 2 times to 4 times larger than the second width.

19. The method according to claim 11, wherein the metal-containing portion comprises metal silicide or metal.

20. The method according to claim 11, wherein the metal-containing portion has a thickness in a range of 200 Å to 400 Å.
